(19) United States
(12) Patent Application Publication
(10) Pub. No.: US 2006/0060980 A1
(43) Pub. Date: Mar. 23, 2006

(54) IC PACKAGE HAVING GROUND IC CHIP AND METHOD OF MANUFACTURING SAME

(75) Inventors: PEI-HAW TSAO, Tai-chung (TW); Chuen-Jye LIN, Tai-chung County (TW); Szu-Wei LU, Hsinchu City (TW); Ching Chun LU, Taipei (TW); Chender HUANG, Hsin-Chu (TW); Mirng-Ji LII, Lujhu Township (TW)

Correspondence Address: BAKER & MCKENZIE;ON BEHALF OF TSMC, 2300 TRAMMELL CROW CENTER, 2001 ROSS AVENUE, SUITE 2300, DALLAS, TX, 75201, US

(73) Assignee: TAIWAN SEMICONDUCTOR MANUFACTURING COMPANY, LTD., Hsin-Chu (TW)

(21) Appl. No.: 10/711,503

(22) Filed: Sep. 22, 2004

(51) Int. Cl. H01L 21/44; H01L 21/48; H01L 21/50; H01L 23/48; H01L 23/52; H01L 29/40

(52) U.S. Cl. 257/778; 438/125

(57) ABSTRACT

Disclosed is a method of manufacturing a semiconductor package device. In one embodiment, the method includes providing a package substrate having a first coefficient of thermal expansion and at least one bonding pad on the substrate. The method also includes forming an integrated circuit chip having electrical devices, having at least one coupling structure for electrically coupling the chip to the at least one bonding pad, and having a second coefficient of thermal expansion different than the first coefficient of thermal expansion. The method further includes removing a portion of a thickness of the chip that is free of the electrical devices sufficient to allow the chip to distort substantially with the substrate during temperature changes despite the mismatch in their respective coefficients of thermal expansion. The method also includes bonding the chip to the substrate using the at least one coupling structure and the at least one bonding pad.

### TECHNICAL FIELD

Disclosed embodiments herein relate generally to mounting integrated circuit (IC) chips on semiconductor package substrates, and more particularly to methods of manufacturing a semiconductor package device including removing a portion of the thickness of the chip sufficient to allow the chip to distort substantially in accordance with the package substrate during temperature changes despite a mismatch in their coefficients of thermal expansion.

### BACKGROUND

The packaging of integrated circuit (IC) chips is one of the most important steps in the manufacturing process, contributing significantly to the overall cost, performance and reliability of the packaged chip. As semiconductor devices reach higher levels of integration, packaging technologies, such as chip bonding, have become critical. Packaging of the IC chip accounts for a considerable portion of the cost of producing the device and failure of the package leads to costly yield reduction.

As semiconductor device sizes have decreased, the density of devices on a chip has increased, along with the size of the chip, thereby making chip bonding more challenging. Many chip bonding technologies use solder bumps attached to a contact pad (the bonding pad) on the chip to make an electrical (and somewhat structural) connection from the chip to the package substrate. For example, C4 (Controlled-Collapse Chip Connection) is a means of connecting semiconductor chips to substrates in electronic packages. C4 is a flip-chip technology in which the interconnections are small solder balls (bumps) on the chip bonding pads. Since the solder balls form an area array (a “ball grid array” (BGA)), C4 technology can achieve a very high-density scheme for chip interconnections. The flip-chip method has the advantage of achieving a very high density of interconnection to the device with a very low parasitic inductance.

One of the major problems leading to package failure as chip sizes decrease and densities increase is the increasingly difficult problem of coefficient of thermal expansion (CTE) mismatches between materials leading to stress (e.g., shear stress) buildup and consequent failure. Specifically, there is typically a mismatch of the CTE between the IC chip and the package substrate, which becomes especially problematic when the package is under thermal load. These stresses will often lead to flip-chip bump joint cracking, which is the fracture or complete separation of the metallurgical bond between the solder balls and the bonding pads. To resolve the bump joint cracking issue, an “underfill” (i.e., an encapsulant) is placed between the IC chip and the package substrate, and around the solder bumps, to assist in resisting bump joint cracking. Although somewhat successful, when lead-free solder material is used to create the solder bumps (e.g., Sn/Ag/Cu, Sn/Ag, or Sn/Cu), the likelihood of bump joint cracking is typically increased due to increased brittleness of lead-free solder materials over lead-based solders (e.g., Sn5/Pb895) and even eutectic solders (e.g., Sn63/Pb37). When bump joint cracking occurs, it is often necessary to repackage the chip after a package failure, requiring costly detachment of the chip from the package and repeating the chip bonding process in a new package. Accordingly, what is needed is a technique for packaging IC chips using lead-free solder in flip-chip techniques that does not suffer from the deficiencies found in the prior art.

### SUMMARY

Disclosed herein is a method of manufacturing a semiconductor package device. In one embodiment, the method includes providing a package substrate having a first coefficient of thermal expansion and at least one bonding pad on a surface of the package substrate. The method also includes forming an integrated circuit chip having electrical devices and having at least one coupling structure for electrically coupling the chip to the at least one bonding pad on the package substrate, where the chip has a second coefficient of thermal expansion different than the first coefficient of thermal expansion. The method further includes removing a portion of a thickness of the chip that is free of the electrical devices sufficient to allow the chip to distort substantially with the package substrate during temperature changes despite the mismatch in their respective coefficients of thermal expansion. In such an embodiment, the method also includes bonding the chip to the package substrate using the at least one coupling structure and the at least one bonding pad.

In another aspect, disclosed is a semiconductor package device. In one embodiment, the device includes a package substrate having a first coefficient of thermal expansion and at least one bonding pad on a surface of the package substrate. In addition, the device includes an integrated circuit chip formed from a semiconductor wafer, where the chip comprises electrical devices formed therein, and at least one coupling structure for bonding the chip to the at least one bonding pad on the package substrate. Also, in this embodiment, the chip comprises a second coefficient of thermal expansion different than the first coefficient of thermal expansion. Additionally, the chip in this package device comprises a final thickness less than a thickness of the semiconductor wafer, wherein the final thickness allows the chip to distort substantially with the package substrate during temperature changes despite the mismatch in their respective coefficients of thermal expansion.

### BRIEF DESCRIPTION OF THE DRAWINGS

For a more complete understanding of the principles disclosure herein, and the advantages thereof, reference is now made to the following descriptions taken in conjunction with the accompanying drawings, in which:

FIG. 1 illustrates a side sectional view of one embodiment of an integrated circuit chip package constructed according to the principles disclosed herein;

FIG. 2 illustrates a close-up view of a portion of the IC chip package illustrated in FIG. 1; and

FIG. 3 illustrates a graph having multiple plots for shear stress measured as a function of IC chip (die) thickness.

### DESCRIPTION OF THE EMBODIMENTS

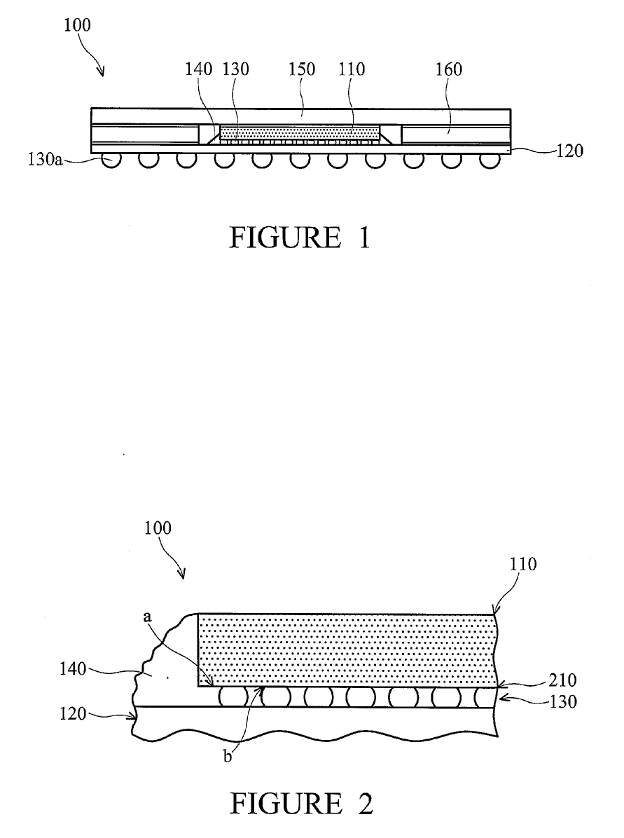

Referring initially to FIG. 1, illustrated is a side sectional view of one embodiment of an IC chip package 100 constructed according to the principles disclosed herein. The package 100 includes an IC chip 110 having a plurality of IC components (e.g., electrical devices) formed therein to form an operable circuit. The IC chip 110 is to be mounted on a package substrate 120 for protection from the ambient environment, and for carrying the IC chip 110 for later mounting of the completed package 100 to, for example, a circuit board.

The IC chip 110 is mounted on the substrate 120 using a flip-chip bonding technique, such as one of the techniques described above. Such flip-chip techniques employ solder balls (one of which is labeled 130) formed in a BGA on a surface of the IC chip 110, and which may then be metallurgically bonded to specific bonding pads on a mounting surface of the substrate 120. The substrate 120 may also have its own BGA 130a on an opposing surface for mounting the completed package 100 to another component. Once the IC chip 110 is mounted on the substrate 120, an underfill material 140 (e.g., an encapsulant) is typically provided between the IC chip 110 and the package substrate 120, surrounding the solder balls 130. Such an underfill 140 is provided to assist in resisting bump joint cracking, which is the cracking (and usually separation) of the solder balls 130 from the IC chip 110 caused by the IC chip 110 and substrate 120 distorting in different manners due to a mismatch in the CTE between the material comprising the IC chip 110 and the material comprising the package substrate 120.

While often successful in resisting bump joint cracking, the use of lead-free solders may be desired, or even required, in the manufacture of the IC package 100. Examples of such lead-free solders include Sn/Ag/Cu, Sn/Ag, and Sn/Cu, but while such solder materials may provide several advantages over lead-based solders, the likelihood of bump joint cracking typically increases. This increase is due primarily to the increased brittleness of lead-free solder materials over lead-based solders (e.g., Sn5/Pb895) and even eutectic solders that still contain lead (e.g., Sn63/Pb37). Thus, because the mismatch in CTE between the IC chip 110 and substrate 120 still exists, and because lead-free solders are typically more brittle, the likelihood of bump joint cracking increases. This is the case even with the use of a heat spreader 150 coupled to an upper surface of the IC chip 110, and stiffeners 160 coupled between the heat spreader 150 and the substrate 120.

The IC package 100 illustrated in FIG. 1 and manufactured according to the principles disclosed herein overcomes the bump joint cracking problem typically found in conventional packages. Specifically, one embodiment of the disclosed manufacturing process provides for back-grinding the thickness of the IC chip 110 prior to mounting it on the package substrate 120. By removing a significant portion of the thickness of the IC chip 110, the stresses caused by the mismatch in CTE of the IC chip 110 and the substrate 120 may be reduced to the point of preventing bump joint cracking fro occurring in the finished package. More specifically, while the CTE of both the IC chip 110 and the substrate 120 remains unchanged (since they are still each made from their same material), material removal as disclosed herein results in the decrease of the ability of the IC chip 110 to distort differently than the substrate 120. Once the IC chip 110 is made significantly thinner, it will then have a tendency to distort in the same manner as, and substantially in accordance with, any distortion in the substrate 120 during temperature variations. Thus, as the IC chip 110 becomes thinner, it becomes more likely to conform to the shape, distortion, or curvature of the substrate 120, rather than trying to pull away from the substrate 120 in various places, which is what typically leads to bump joint cracking and other similar defects. This, therefore, results in decreasing the impact of the CTE mismatch between the two during increased temperatures.

In a specific embodiment, the disclosed process provides for grinding away, or otherwise removing, at least half of the thickness of the IC chip 110 from the surface or side that is free of IC devices. In some embodiments, two-thirds or even more of the thickness of the IC chip 110 may be removed from the IC chip 110. For example, a common semiconductor wafer from which the IC chip 110 is cut typically has a thickness of about 29 to 31 mils. By following the disclosed approach, the IC chip 110 is ground down to a final thickness of about 3-8 mils. In another embodiment, the removing of the thickness of the IC chip 110 may be done while the IC chip 110 is still part of the semiconductor wafer (i.e., while it is still a “die”). In such an embodiment, the entire wafer may be ground down after formation of the IC dies on the wafer is complete. In other embodiments, however, the removing of thickness of the IC chip 110 may occur after the wafer has been diced into individual chips, but before the IC chip 110 is mounted on the substrate 120. In still other embodiments, the removal of chip thickness may be accomplished after the IC chip 110 is mounted to the package substrate 120.

Turning now to FIG. 2, illustrated is a close-up view of a portion of the IC chip package 100 illustrated in FIG. 1. As before, the package 100 includes an IC chip 110 mounted on a package substrate 120 by metallurgically bonding an array of solder balls 130 using a flip-chip bonding technique. The dielectric underfill material 140 surrounding the metallurgical bonds between the bonding pads of the IC chip 110 and the substrate 120 is also illustrated.

Now visible in this close-up view is an inter-metal dielectric (IMD) layer 210 formed at the bottom surface of the IC chip 110, closest to the package substrate 120. Such IMD layers 210 are typically low-K (e.g., K<3.5) dielectric layers accompanied by a thin metal layer(s), such copper (Cu). Examples of low-K dielectric materials includes Black Diamond®, SiLK®, and CORAL®. In recent years, the use of copper metallization and low-K dielectrics at the IMD layer 210 have promised faster performance, smaller chip sizes, and lower overall power consumption. Unfortunately, the usual superior electrical performance of low-K IMD layers 210 comes at the expense of inferior mechanical and thermal characteristics. Due to such problems, some manufacturers have begun incorporating low-K IMD layers 210 only at the bottom dense signal routing layers of the IC chip 110, where most of the signal routing wires reside. However, because these layers are closer to the passivation layer and bonding pads, or flip-chip “bumping” layer, where the stress level is usually the most significant and critical, regular SiO₂ instead of low-K IMD has been employed in an attempt to avoid failures in the bonding between the IMD layer 210 and the solder balls 130.

When ceramic package substrates are used in package manufacture, the bonding reliability of the IC chip 110 to the package substrate 120 is often relatively good. However, if an organic (plastic) package substrate 120 is used, additional manufacturing steps, for example, the use of the underfill 140, are typically required to ensure a reliable interconnection. This is primarily due to the difference in the CTE between the IC chip 110 and the package substrate 120 discussed in detail above. As a result, the CTE mismatch between the IC chip 110 and the substrate 120 results in a bending or curving of the package assembly 100, and thus the IC chip 110, when temperature changes. Specifically, since the IC chip 110 and the substrate 120 have significantly different CTE, each component of the package 100 typically bends in a different manner and to a different degree. Thus, as the temperature changes, the likelihood of delamination of the low-K IMD layer 210 material from the metal stack of the IC chip 110, as well as cracking in the low-K material, further increase. These problems are in addition to the potential for bump joint cracking discussed above.

In spite of the common problem of bump joint cracking, organic packaging technology has become pervasive due to its excellent electrical properties and its relative low cost compared to ceramic technologies. In addition, wire bonding packaging techniques are also susceptible to such CTE mismatch of the silicon IC chip 110 and the organic substrate 120, although failure modes attributed to CTE mismatch in wire bonded packages are traditionally not as pronounced as they are in flip-chip packaging. However, even the most modern wire bonding packaging techniques are challenged to support ever shrinking chip sizes and electrical performance demands. Thus, flip-chip packaging techniques, although susceptible to bump joint cracking and delamination at the IMD layer 210, are still the packing technique of choice for most manufacturers.

Fortunately, the disclosed technique of decreasing the thickness of the IC chip 110 from that of the original semiconductor wafer prior to mounting the IC chip 110 on the package substrate 120 also address the problem of delamination at the low-K IMD layer 210. As with preventing bump joint cracking, the disclosed technique is also beneficial for reducing such delamination in applications employing lead-free solders. Thus, as before, once the IC chip 110 is made significantly thinner by remove a significant amount of its thickness, it will then have a tendency to distort in the same manner as, and in accordance with, the substrate 120 during temperature variations. Thus, the IC chip 110 becomes more likely to conform to the shape of the substrate 120, therefore decreasing the impact of the CTE mismatch between the two and decreasing the likelihood of delamination at the IMD layer 210, in addition to reducing the chance of bump joint cracking.

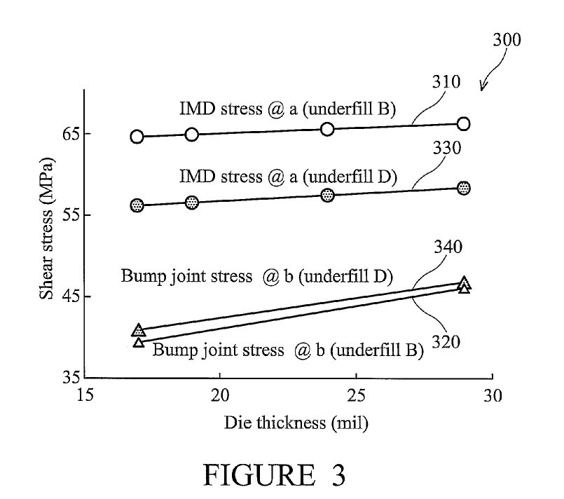

Turning finally to FIG. 3, illustrated is a graph 300 having multiple plots for shear stress measured as a function of IC chip (die) thickness. Generally speaking, the graph 300 demonstrates the marked decrease in shear stress between the IC chip 110 and the package substrate 120 during temperature changes. As illustrated in the graph 300, and with reference back to FIG. 2, the shear stress is measured at the IMD layer 210 and at the joint between the solder bumps 130 and the bonding pads of the IC chip 110.

Looking specifically at the individual plots, plot 310 illustrates the decrease in IMD layer 210 shear stress at point “a” in FIG. 2 when a first underfill material (“underfill B”) is used in the package device. Plot 320 illustrates the decrease in bump joint shear stress at point “b” in FIG. 2 when the first underfill material is used in the package device. Plot 330 illustrates the decrease in IMD layer 210 shear stress at point “a” when a second underfill material (“underfill D”) is used in the package device. Finally, plot 340 illustrates the decrease in bump joint shear stress at point “b” also when the second underfill material is used in the package device. As may be seen with the various plots in the graph 300, in addition to the benefits provided by decreasing the thickness of the IC chip 110 as disclosed herein, further decreases in shear stress at critical points of connection may also be achieved by combining the disclosed approach with various underfill materials selected depending on the application.

While various embodiments of forming a semiconductor package device according to the principles disclosed herein have been described above, it should be understood that they have been presented by way of example only, and not limitation. Thus, the breadth and scope of the invention(s) should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the invention(s) set out in any claims that may issue from this disclosure. Specifically and by way of example, although the headings refer to a “Technical Field,” such claims should not be limited by the language chosen under this heading to describe the so-called technical field. Further, a description of a technology in the “Background” is not to be construed as an admission that technology is prior art to any invention(s) in this disclosure. Neither is the “Brief Summary” to be considered as a characterization of the invention(s) set forth in issued claims. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings set forth herein.

1-15. (canceled)

16. A semiconductor package device, comprising:
a package substrate having a first coefficient of thermal expansion and at least one bonding pad on a surface of the package substrate; and
an integrated circuit chip formed from a semiconductor wafer, the chip comprising:
electrical devices formed therein,
at least one coupling structure for bonding the chip to the at least one bonding pad on the package substrate,
a second coefficient of thermal expansion different than the first coefficient of thermal expansion, and
a final thickness less than a thickness of the semiconductor wafer, wherein the final thickness allows the chip to distort substantially with the package substrate during temperature changes despite the mismatch in their respective coefficients of thermal expansion.

17. A semiconductor package device according to claim 16, wherein the final thickness is about one-third of the thickness of the semiconductor wafer.

18. A semiconductor package device according to claim 16, wherein the thickness of the semiconductor wafer is about 29 to 31 mils and the final thickness of the chip is about 3-8 mils.

19. A semiconductor package device according to claim 16, further comprising a heat spreader coupled to a surface of the chip free of electrical devices.

20. A semiconductor package device according to claim 16, wherein the at least one coupling structure comprises a metal.

21. A semiconductor package device according to claim 16, wherein the at least one coupling structure is lead-free.

22. A semiconductor package device according to claim 16, wherein the at least one coupling structure is a solder ball.

23. A semiconductor package device according to claim 16, further comprising an inter-metal dielectric layer adjacent to a surface of the chip that is closest to the package substrate, and wherein the at least one coupling structure is located adjacent to the inter-metal dielectric layer.

24. A semiconductor package device according to claim 16, further comprising a dielectric encapsulant between the chip and the package substrate, the dielectric encapsulant substantially surrounding the at least one coupling structure and the at least one bonding pad.

25. A semiconductor package device according to claim 16, wherein the package substrate is selected from the group consisting of glass, ceramic, a silicon-on-insulator, a polymer, silicon, silicon germanium, a single layer printed circuit board having conductive traces formed therein, and a multi-layer printed circuit board having conductive traces formed therein.

26. A semiconductor package device according to claim 16, wherein the chip comprises at least one coupling structure for metallurgically bonding the chip to the at least one bonding pad on the package substrate.
